(19) United States
(12) Patent Application Publication
(10) Pub. No.: US 2015/0299850 A1
(43) Pub. Date: Oct. 22, 2015

(54) Graphene Spin Filters via Chemical Vapor Deposition

(71) Applicants: Enrique Cobas, Capitol Heights, MD (US); Olaf M. T. van 't Erve, Falls Church, VA (US); Adam L. Friedman, Silver Spring, MD (US); Berend T. Jonker, Waldorf, MD (US)

(72) Inventors: Enrique Cobas, Capitol Heights, MD (US); Olaf M. T. van 't Erve, Falls Church, VA (US); Adam L. Friedman, Silver Spring, MD (US); Berend T. Jonker, Waldorf, MD (US)

(73) Assignee: The Government of the United States of America, as represented by the Secretary of the Navy, Washington, DC (US)

(21) Appl. No.: 14/657,665

(22) Filed: Mar. 13, 2015

Related U.S. Application Data
(60) Provisional application No. 61/980,483, filed on Apr. 16, 2014.

(51) Int. Cl. C23C 16/26; C23C 16/455; C23C 16/46; C23C 16/44

(52) U.S. Cl. CPC C23C 16/26; C23C 16/44; C23C 16/455; C23C 16/46; C23C 16/463

(57) ABSTRACT

A method of making a graphene spin filter device by chemical vapor deposition comprising providing a first crystalline ferromagnetic metal surface, performing chemical vapor deposition and growing a graphene film on the first ferromagnetic metal surface, and depositing a second ferromagnetic film on the graphene film. A graphene spin filter device wherein the graphene is grown by chemical vapor deposition comprising a first crystalline ferromagnetic metal surface, a graphene film grown by chemical vapor deposition on the first ferromagnetic metal surface, and a second ferromagnetic film on the graphene film.

This application claims priority to and the benefits of U.S. patent application Ser. No. 61/980,483 filed on Apr. 16, 2014, the entirety of which is herein incorporated by reference.

### BACKGROUND

Described herein are spin filtering layered structures created by growth of a few-layer graphene film directly on a ferromagnetic metal surface, followed by deposition of a second ferromagnetic film over the graphene film.

This spin-filtered interface can be queried electronically to determine the magnetization of the first magnetic layer in relation to the second magnetic layer.

These devices have applications in any technology employing fast and sensitive readout of the magnetization of a thin film, including magnetic sensors, hard drive read heads and non-volatile magnetic information storage.

The band structure of graphene, as calculated by Wallace, includes quantum states with unique momentum and energy restrictions: at low energies near the Fermi level, only states with momentum K exist in graphene. Therefore graphene only supports transmission of carriers with momentum K As explained by Karpan et al. and Yazyev & Pasquarello, the planar crystal lattice parameters of graphene are very similar to those of close-packed ferromagnetic metal surfaces like Nickel (111) and Cobalt (0002). These ferromagnetic surfaces have different band structures for majority spin and minority spin electrons and, at low energies, have only minority spin electron states with momentum K. Since only minority spin carriers with momentum K exist in the ferromagnet, and only carriers with momentum K can exist in the graphene lattice, then only minority spin carriers can be transferred from the ferromagnet to the graphene. This is the nature of a spin filter.

For electrons with momentum different than K, the graphene is effectively an insulator or tunnel barrier. The transmission probability of electrons passing through such a spin filter interface and onto a second ferromagnetic film depends sensitively on the relative magnetizations of the two ferromagnetic layers. Thus the spin filtering effect can be used to electrically determine the magnetization of a second ferromagnetic layer which lies on the other side of a few-layer graphene film. Technological applications for such sensitive magnetization detectors include magnetic field sensors and fast magnetic random access memory (MRAM) data storage technologies.

### BRIEF SUMMARY OF THE INVENTION

A crystalline ferromagnetic metal film with close-packed (111) surface is deposited onto a substrate. Few-layer graphene/graphite is synthesized on the ferromagnetic film by exposure to a high-temperature ambient in the presence of a source of carbon (such as hydrocarbons, alcohols, solid or melted polymer films or amorphous carbon films) and subsequent cooling. To observe and make use of the spin filtering effect electrically, a second ferromagnetic film is then deposited over the graphene film and the mutli-layer stack can be patterned into electrically addressable test structures. The particulars of our reduction to practice, described below, are limited possible variations of the general method.

### BRIEF DESCRIPTION OF THE DRAWINGS

FIG. 1 illustrates X-ray diffraction spectrum of a Ni_{0.8}Fe_{0.2} (111) film sputtered onto Al₂O₃ (0002) at 500C at a thickness of 300 nm.

FIG. 2 illustrates Reflection High-Energy Electron Diffraction (RHEED) pattern of a Ni_{0.8}Fe_{0.2} (111) film sputtered onto Al₂O₃ (0002) at 500C at a thickness of 300 nm.

FIG. 3 illustrates average Raman spectrum of a few-layer graphene/graphite film grown on a Ni_{0.8}Fe_{0.2} (111) film. This is the typical Raman signature of good-quality multi-layer graphene or graphite.

FIG. 4 illustrates a diagram of a an electrically addressable ferromagnet-graphene-ferromagnet test structure.

FIG. 5 illustrates a three-dimensional rendering of Atomic Force Microscope (AFM) data displaying a test structure similar to that described in FIG. 4.

FIG. 6 illustrates an optical micrograph of a NiFe-Graphene-Fe junction prior to top lead deposition. Junction (mesa) diameter is 22 μm.

FIG. 7 illustrates an optical micrograph of a four-probe graphene junction prior to top metal deposition, displaying the central NiFe/Graphene/Fe mesa and access via.

FIG. 8A illustrates magnetoresistance of a typical few-layer graphene junction at 15K as a function of applied magnetic field at bias currents of 1 mA to 7 mA. FIG. 8B illustrates peak magnetoresistance vs. applied junction bias voltage at 15K.

FIG. 9A illustrates characteristic negative magnetoresistance as a function of applied field for temperatures between 25K and 250K. FIG. 9B illustrates measured peak negative magnetoresistance versus temperature over the same temperature range.

### DETAILED DESCRIPTION

Briefly, a crystalline ferromagnetic metal film with close-packed (111) surface is deposited onto a substrate. Few-layer graphene/graphite is synthesized on the ferromagnetic film by exposure to a high-temperature ambient in the presence of a source of carbon and subsequent cooling. Example sources of carbon include but are not limited to hydrocarbons, alcohols, solid or melted polymer films or amorphous carbon films.

To observe and make use of the spin filtering effect electrically, a second ferromagnetic film is then deposited over the graphene film and the mutli-layer stack can be patterned into electrically addressable test structures.

The particulars of our reduction to practice, described below, are only one embodiment or variation of the general method.

### Example 1

### Ferromagnetic Film Deposition

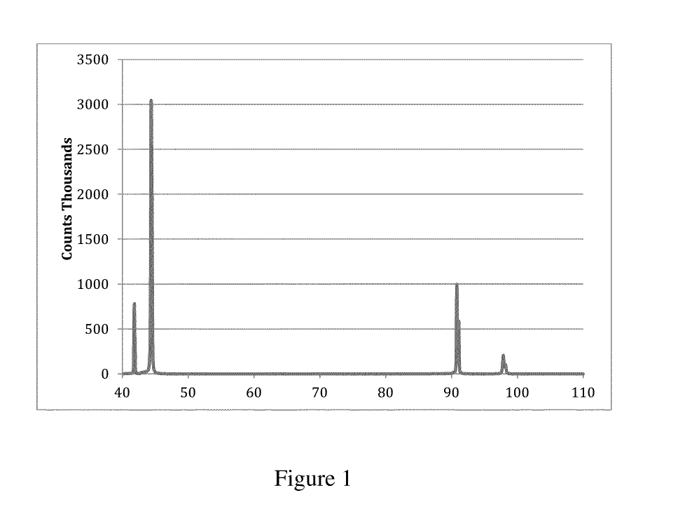

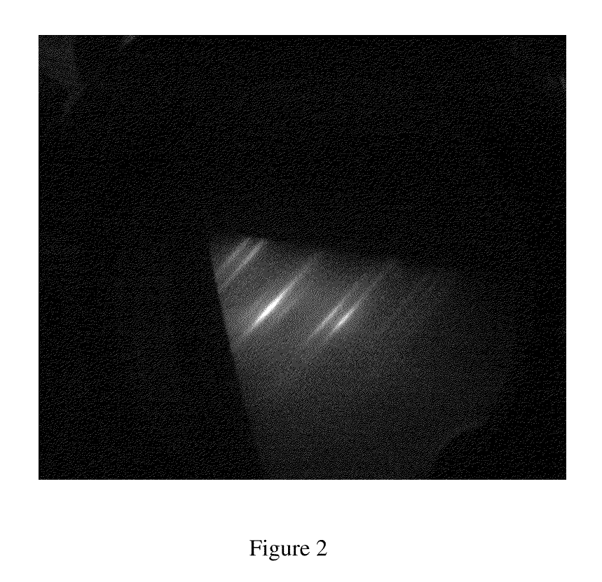

A 200 nm thick film of Permalloy (Ni_{0.8}Fe_{0.2}) was deposited onto a c-plane Sapphire (0002) wafer via sputtering. The crystal orientation of the Permalloy film was checked by x-ray diffraction and reflection high energy electron diffraction, which confirmed the predominantly (111) Permalloy surface orientation. (FIGS. 1 and 2).

### Example 2

### Graphene Film Synthesis

The sample was placed into the unheated portion of a 2.75″ diameter quartz tube which protruded out of a tube furnace. Argon and Hydrogen flows of 200 sccm and 500 sccm respectively were inserted into the tube for 100 minutes (20 L and 50 L of Argon and Hydrogen, respectively) and an 18″ portion of the tube was heated to 900C.

The sample was annealed for 10 minutes at 900C in Argon and Hydrogen atmosphere (200 sccm and 400 sccm, respectively) by moving it into the heated portion of the tube. For graphene growth, the feed gases were then replaced by Methane (100 sccm) and Hydrogen (200 sccm) for 30 minutes.

Cooling was done in two stages: First from 900C to 575C at an average rate of 9C/min under Argon-Hydrogen flow (200 sccm Argon, 20 sccm Hydrogen). From 575C to room temperature, the sample was moved to the unheated portion of the tube while the gas flows remained unchanged (Ar 200 sccm, H₂ 20 sccm).

### Example 3

### Graphene Film Characterization

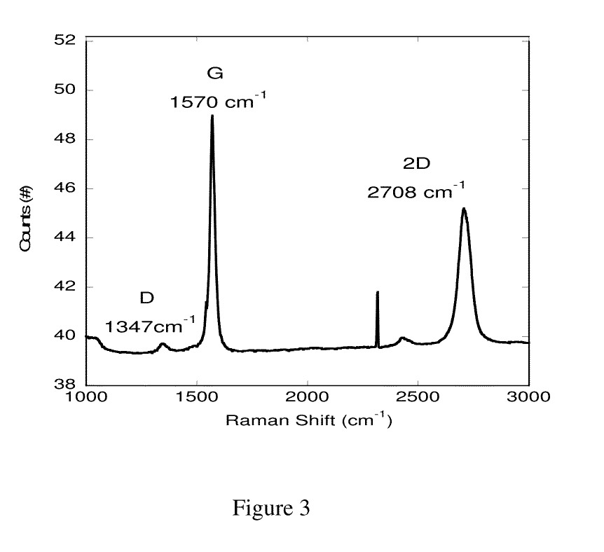

The presence of graphene was ascertained by inspection in an optical microscope and subsequently by Raman spectroscopy (FIG. 3). The quality and thickness of the graphene film was determined by analysis of the Raman signals, in particular the intensity of the D peak in relation to the primary G peak, and the area encompassed by the 2D peak in relation to the G peak. The sample was rastered by a motorized stage in a custom-built Raman spectrometer to map the spatial uniformity of the graphene film properties.

Atomic Force Microscopy was used to determine the resulting RMS roughness of the sample and Vibrating Sample Magnetometry (VSM) was used to measure the magnetic switching properties of the Permalloy film and confirm its high magnetic quality even after high temperature graphene growth.

### Example 4

### Spin Filter Test Structure Fabrication

A thin film of Iron (25 nm) was deposited over the graphene film using an electron-beam deposition system at high vacuum (10⁻⁶ Ton). Standard industry microfabrication techniques were used to pattern the film into high-aspect-ratio rectangular mesas by ion milling down to the Sapphire substrate. These features were later also milled down to the Permalloy layer, with the exception of a central Fe/Graphene/NiFe mesa, which is the tested junction area.

The remainder of the Permalloy feature serves as the electrical lead to the bottom of the junction. Two junction diameters were used: 17 μm and 22 μm. A SiN spacer film, thickness 60 nm was deposited by sputtering and shaped by lift-off with a 9 μm or 16 μm diameter via hole exposing the top of the Fe/Graphene/NiFe mesa. Ti/Au bond pads were patterned by liftoff and deposited with a short pre-deposition mill step to remove surface oxidation at the NiFe leads.

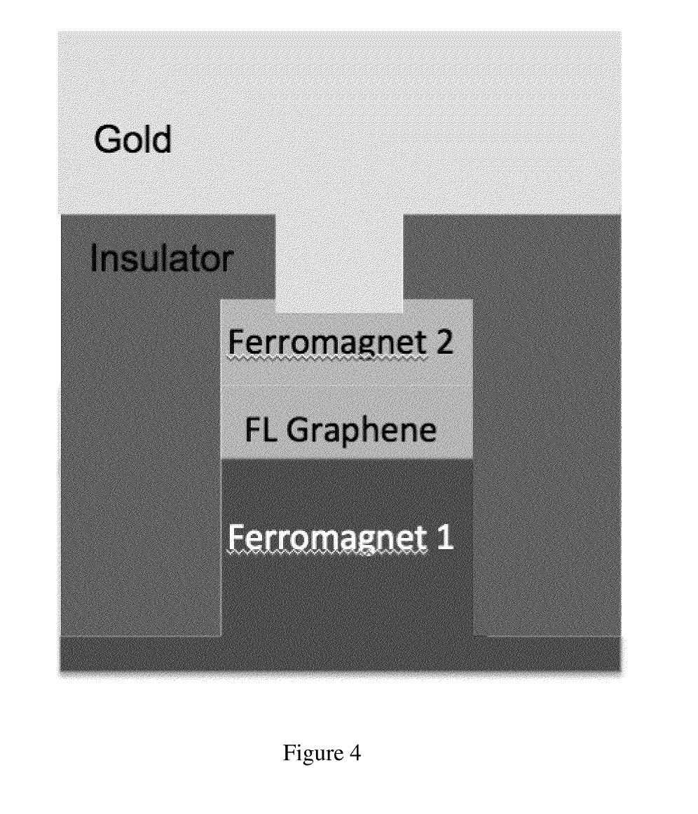

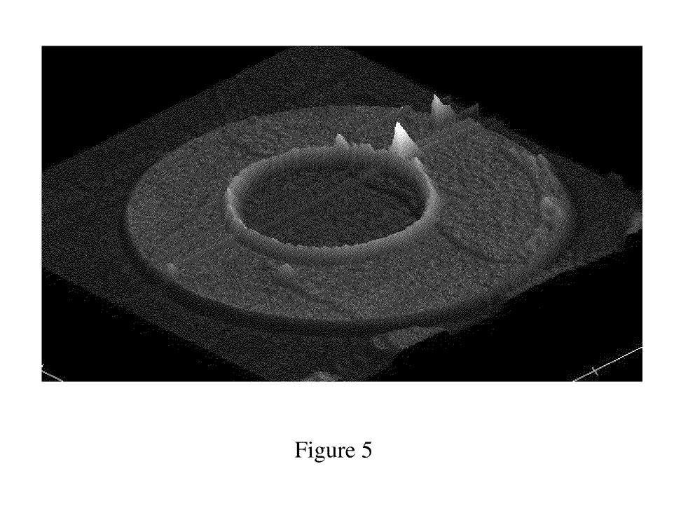

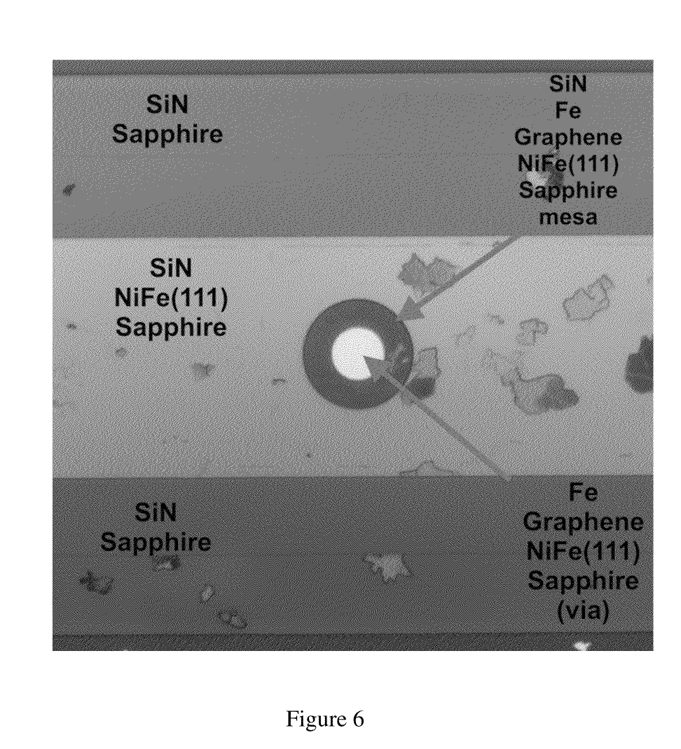

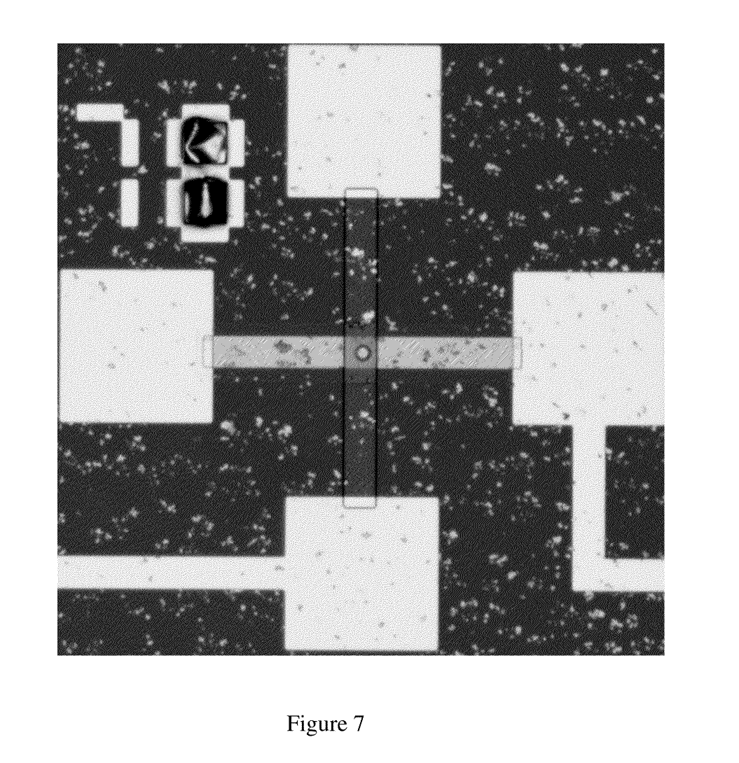

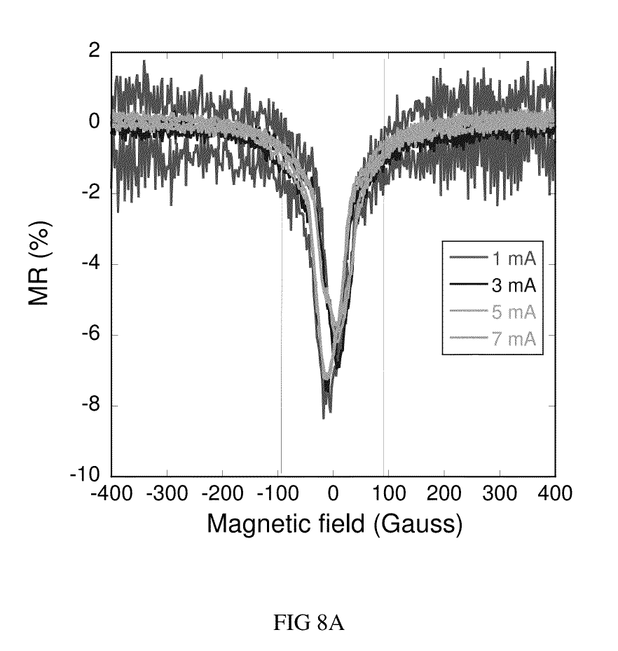

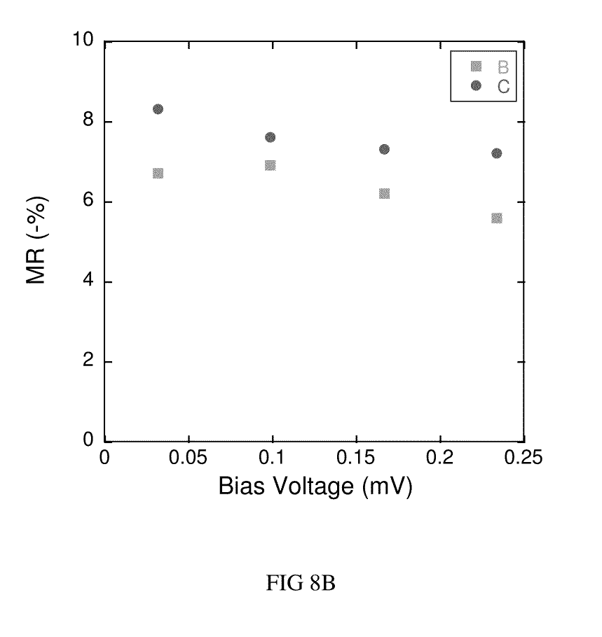

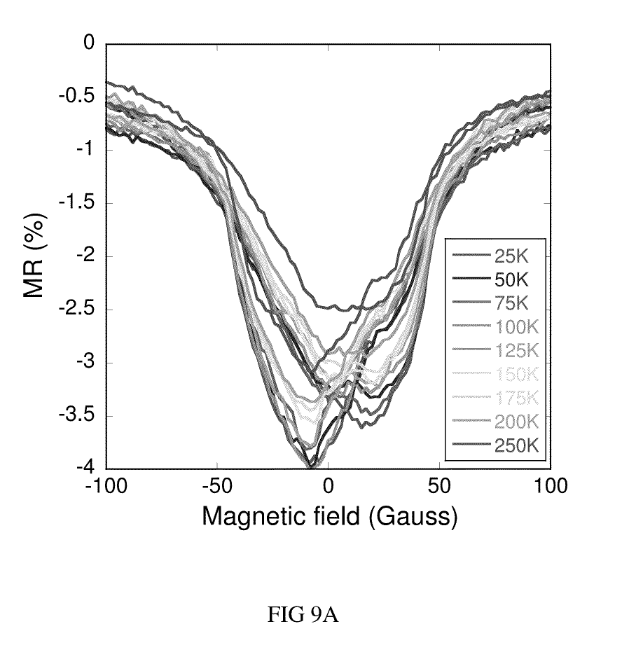

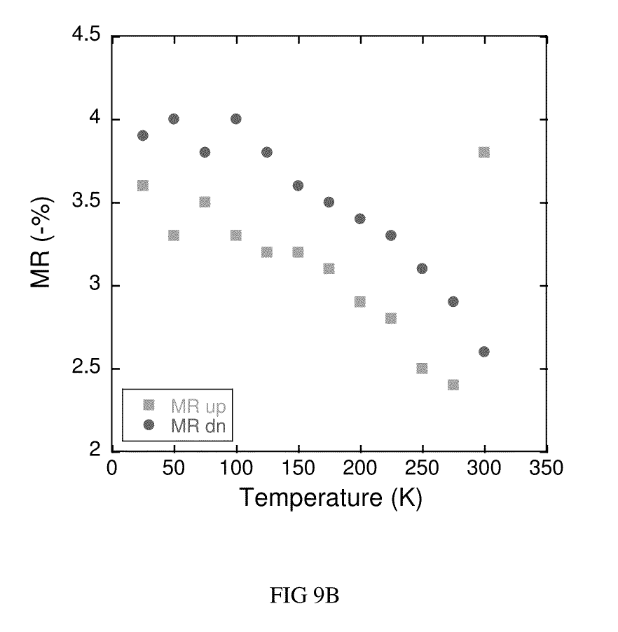

Then, the top lead, perpendicular to the elongated NiFe lead was patterned over the junction via. The top 10 nm of the Fe were milled away to remove surface oxidation before deposition of the Ti/Au lead, completing the test structures (FIGS. 4-8).

### Example 5

### Confirmation of Spin Filtering Effect

The junction array was placed in a probe station with a variable-field electromagnet capable of sweeping the magnetic field from −280 Gauss to +280 Gauss. A positive current of +5 mA was applied to two leads of the test structure connected to the top and bottom of the junction stack using a Keithley model 2600 Source Meter in Current Source mode.

The applied voltage from the Current Source was measured by a Keithley 2000 voltmeter while the potential difference between the two other leads (top and bottom of the junction) was measured by a Keithley 2000 voltmeter in a standard four-probe electrical measurement.

The resistance of the current circuit was of order 10 Ω, mostly attributable to the NiFe lead and Au lead resistances. The voltage difference between the top and bottom leads in the immediate proximity of the junction was of order +0.1 mV, corresponding to a junction resistance of order 20 mΩ. An external electromagnet was used to apply a variable magnetic field to the sample perpendicular to the current direction in the Permalloy lead (and parallel to current in the nonmagnetic Ti/Au lead).

The resistance of the current circuit, dominated by the Permalloy lead's resistance, exhibited 1.5% lower resistance at high applied fields (|B|>30 Gauss), as expected for anisotropic magnetoresistance (AMR) of Permalloy with the field perpendicular to the current flow. In contrast, the resistance of the NiFe/Graphene/Fe spin filter junction increased about 5% under applied field (|B|>50 Gauss) at room temperature, commonly noted as negative magnetoresistance.

The two-dimensional layered nature of graphene offers significant advantages when incorporated into a layered heterostructures. Replacement of insulating oxide films with a few-layer graphene films (1) removes the dangling bonds inherent in three-dimensional crystalline and amorphous materials thereby preventing formation of unwanted compounds at the interface between films, (2) provides control of the film thickness in discrete 0.3 nm steps down to monoatomic 0.3 nm thickness that is unachievable with competing materials, (3) reduces the number of unwanted “pin-hole” gaps in films of comparable thickness, (4) enables high-temperature processing without diffusion of barrier materials into the electrodes, (5) creates as a diffusion barrier preventing inter-diffusion of the two metal layers at high temperatures needed for subsequent processing, (6) provides significantly lower resistivity (3.9 Ω-μm) than competing technologies with similar magnetoresistance performance, and (7) provides enhanced resistance to ionizing radiation through the high lateral conductance of the graphene film.

Competing MRAM technologies use either MgO tunnel barriers or Al₂O₃ tunnel barriers between the ferromagnetic layers. These alternatives are subject to the drawbacks described above. Namely, in the prior art, the three-dimensional nature of the oxide materials makes thickness control a challenge, higher defect densities produce flaws in very thin films, the dangling bonds form unwanted compounds at the interfaces and the oxide materials may diffuse into the metal layers at elevated temperatures, limiting the subsequent processing parameters. To accommodate these drawbacks, prior art technologies use thicker oxide films with reduced performance and limit the subsequent processing temperatures. The invention described herein overcomes these prior art limitations.

Many modifications and variations of the present invention are possible in light of the above teachings. It is therefore to be understood that the claimed invention may be practiced otherwise than as specifically described. Any reference to claim elements in the singular, e.g., using the articles “a,” “an,” “the,” or “said” is not construed as limiting the element to the singular.

What we claim is:

1. A method of making a graphene spin filter device by chemical vapor deposition, comprising:
providing a first crystalline ferromagnetic metal surface;
performing chemical vapor deposition and growing a graphene film on the first crystalline ferromagnetic metal surface; and
depositing a second ferromagnetic film on the graphene film.

2. The method of making the graphene spin filter device by chemical vapor deposition of claim 1, wherein the steps of performing chemical vapor deposition and growing a graphene film on the first crystalline ferromagnetic metal surface comprise the steps of:
providing a source of carbon;
exposing the first crystalline ferromagnetic metal surface to a high-temperature ambient in the presence of the source of carbon;
growing graphene or graphite on the first crystalline ferromagnetic metal surface; and
cooling.

3. The method of making the graphene spin filter device by chemical vapor deposition of claim 2, further comprising the steps of:
completing a spin filtered interface; and
querying electronically the spin filtered interface.

4. The method of making a graphene spin filter device by chemical vapor deposition of claim 3 wherein the step of completing the spin filtered interface comprises the step of:
patterning the graphene spin filter device into an electrically addressable structure.

5. The method of making the graphene spin filter device by chemical vapor deposition of claim 2 wherein the first crystalline ferromagnetic metal surface has a close-packed (111) surface.

6. The method of making the graphene spin filter device by chemical vapor deposition of claim 2 wherein the source of carbon is one selected from the group consisting of hydrocarbons, alcohols, solid polymer films, melted polymer films, and amorphous carbon films.

7. The method of making the graphene spin filter device by chemical vapor deposition of claim 6 wherein the first crystalline ferromagnetic metal surface comprises NiFe.

8. The method of making the graphene spin filter device by chemical vapor deposition of claim 7 wherein the second ferromagnetic film comprises Fe.

9. The method of making the graphene spin filter device by chemical vapor deposition of claim 2 wherein the steps of performing chemical vapor deposition and growing a graphene film on the first crystalline ferromagnetic metal surface are performed without the use of a vacuum.

10. A method of making a graphene spin filter device by chemical vapor deposition, comprising:
providing a first crystalline ferromagnetic metal surface;
providing a carbon source;
placing the first crystalline ferromagnetic metal surface and the carbon source into an unheated portion of a tube;
flowing a first gas mixture into the tube;
heating a portion of the tube;
heating the first crystalline ferromagnetic metal surface and carbon source;
replacing the first gas mixture with a second gas mixture;
growing by chemical vapor deposition a graphene film on the first crystalline ferromagnetic metal surface;
cooling the first crystalline ferromagnetic metal surface and the graphene film under Ar/hydrogen flow;
moving the first crystalline ferromagnetic metal surface and the graphene film to an unheated portion of the tube;
cooling further to room temperature under Ar/hydrogen flow; and
depositing a second ferromagnetic film on the graphene film.

11. The method of making a graphene spin filter device by chemical vapor deposition of claim 10 wherein the first gas mixture comprises Ar and Hydrogen.

12. The method of making a graphene spin filter device by chemical vapor deposition of claim 11 wherein the step of heating a portion of the tube comprises heating the tube to about 900° C. and wherein the step of heating the first crystalline ferromagnetic metal surface and carbon source comprises heating to about 900° C.

13. The method of making a graphene spin filter device by chemical vapor deposition of claim 12 wherein the second gas mixture comprises methane and hydrogen.

14. The method of making a graphene spin filter device by chemical vapor deposition of claim 13 wherein the step of cooling comprises cooling from 900° C.-575° C. at an average rate of about 9° C./min.

15. A graphene spin filter device wherein the graphene is grown by chemical vapor deposition, comprising:
a first crystalline ferromagnetic metal surface;
a graphene film grown by chemical vapor deposition on the first crystalline ferromagnetic metal surface; and
a second ferromagnetic film on the graphene film.
